(19) United States
(12) Patent Application Publication
(10) Pub. No.: US 2015/0001180 A1
(43) Pub. Date: Jan. 1, 2015

(54) PROCESS KIT FOR EDGE CRITICAL DIMENSION UNIFORMITY CONTROL

(71) Applicant: Applied Materials, Inc., Santa Clara, CA (US)

(72) Inventors: Kenny Linh DOAN, San Jose, CA (US); Jason Della ROSA, Campbell, CA (US); Hamid NOORBAKHSH, Fremont, CA (US); Jong Mun KIM, San Jose, CA (US)

(73) Assignee: APPLIED MATERIALS, INC., Santa Clara, CA (US)

(21) Appl. No.: 14/020,774

(22) Filed: Sep. 6, 2013

Related U.S. Application Data
(60) Provisional application No. 61/841,194, filed on Jun. 28, 2013.

(51) Int. Cl. H01J 37/32; B32B 18/00

(52) U.S. Cl. CPC H01J 37/32642; B32B 18/00
USPC 216/67; 156/345.1; 428/446; 428/448

(57) ABSTRACT

A tunable ring assembly, a plasma processing chamber having a tunable ring assembly and method for tuning a plasma process is provided. In one embodiment, a tunable ring assembly includes an outer ceramic ring having an exposed top surface and a bottom surface and an inner silicon ring configured to mate with the outer ceramic ring to define an overlap region, the inner silicon ring having an inner surface, a top surface and a notch formed between the inner surface and the top surface, the inner surface defining an inner diameter of the ring assembly, the notch is sized to accept an edge of a substrate, an outer portion of the top surface of the inner silicon ring configured to contact in the overlap region and underlying an inner portion of the bottom surface of the outer ceramic ring.

### CROSS-REFERENCE TO RELATED APPLICATIONS

This application claims benefit of U.S. Provisional Application Ser. No. 61/841,194, filed Jun. 28, 2013 (Attorney Docket No. APPM/02878USL), of which is incorporated by reference in its entirety.

### BACKGROUND OF THE DISCLOSURE

1. Field of the Invention

The embodiments herein generally relate to controlling the uniformity of critical dimensions along the edge of a substrate during plasma processing. More specifically, the embodiments relate to a tunable ring process kit and a method for use of the same.

2. Description of the Background Art

Various semiconductor fabrication processes, such as plasma-assisted etching, physical vapor deposition, and chemical vapor deposition, among others, are performed in plasma processing chambers in which a semiconductor work piece, engages with a cover ring during processing. For example in a plasma processing chamber configured for etching a work piece, a semiconductor substrate is mounted on a substrate support pedestal within the processing chamber. The substrate support pedestal includes a metal electrode to which an RF bias may be applied. A plasma is formed from a mixture of process gases provided to the processing chamber. The pressure within the processing chamber is maintained by a pump which also removes by-products from the chamber. A power supply is coupled to the electrode inside the substrate support pedestal so as to produce on the electrode a negative bias voltage relative to the plasma. The bias voltage attracts ions from the plasma to bombard the work piece so as to promote the desired fabrication process. Because the electrode is negatively biased, the substrate support pedestal is often called the cathode.

The cathode is typically surrounded by covers and liners to protect the cathode from damage due to the ion bombardment. For example, a liner may be utilized to surround the sidewalls of the cathode, while a cover ring is utilized to cover the upper surface of the cathode. A substrate is positioned inside the cover ring while supported on the pedestal. Ions from, the plasma gas formed in the chamber is biased by the cathode to target the substrate. However during etching, the ions from the plasma have a natural angle of spread which tends to attack the sidewalls of features formed in a substrate. Additionally, the bias in the cover ring is different than the substrate leading to non-uniformity of ions across the surface of the substrate.

As the geometry limits of the structures used to form semiconductor devices are pushed against technology limits, the need for accurate process control in the manufacture of small critical dimensional structures has become increasingly important. Critical dimensions, such as the width or pitch of interconnects, vias, trenches, contacts, devices, gates and other features, as well as the dielectric materials disposed therebetween, are correspondingly decreased. However, non-uniformity of the plasma gas contributes to poor processing results, particularly near the edge of the substrate where it meets the ring.

Some device configurations require deep feature etching to form desired structures. A challenge associated with deep feature etching of features with high aspect ratios is controlling the etch rate in the features formed through multiple layers having different feature densities and the formation of nearly vertical sidewalls due to the non-uniform distribution of ions within the chamber. Poor process control due to non-uniformity of the plasma across the substrate surface during the etching process may result in irregular structure profiles and line edge roughness, thereby resulting in poor line integrity and inaccurate critical dimensions for the formed structures. The irregular profiles and growth of the etching by-products formed during etching may gradually block the openings used to fabricate the structures, thereby resulting in bowed, distorted, toppled, or twisted profiles of the etched structures.

Therefore as feature geometries move toward even higher aspect ratios, maintaining an efficient and precise etching rate has become increasingly difficult to control over the substrate without either under-etching the upper layers or over-etching into the lower layers, particularly across different regions of the substrate. The failure to form the features or patterns on the substrate, as designed, may result in unwanted defects, and adversely affect subsequent process steps, ultimately degrading or disabling the performance of the final integrated circuit structure.

Emerging 3D NAND architecture involves stacks of alternating dielectric layers that intensifies demands placed on the etch system. The etch systems must be capable of exacting profile control across the entire substrate for feature aspect ratios up to 80:1. As critical dimensions (CD) shrink and fabricators strive to pack more devices on a single substrate, there is a need for an improved method and apparatus for etching high aspect ratio features suitable for next-generation semi-conductor devices.

### SUMMARY

Embodiments of the invention provide a tunable ring assembly, a plasma processing chamber having a tunable ring assembly and method for tuning a plasma process. In one embodiment, a tunable ring assembly includes an outer ceramic ring having an exposed top surface and a bottom surface and an inner silicon ring configured to mate with the outer ceramic ring to define an overlap region, the inner silicon ring having an inner surface, a top surface and a notch formed between the inner surface and the top surface, the inner surface defining an inner diameter of the ring assembly, the notch is sized to accept an edge of a substrate, an outer portion of the top surface of the inner silicon ring configured to contact in the overlap region and underlying an inner portion of the bottom surface of the outer ceramic ring.

In another embodiment, a plasma processing chamber is provided. The plasma processing chamber includes a substrate support pedestal disposed in a chamber body. The substrate support pedestal has a cathode electrode disposed therein. A ring assembly is disposed on the substrate support. The ring assembly includes an inner silicon ring configured to mate with an outer ceramic ring to define an overlap region. The outer ceramic ring has an exposed top surface and a bottom surface. The inner silicon ring has an inner surface, a top surface and a notch formed between the inner surface and the top surface. The inner surface defines an inner diameter of the ring assembly. The notch is sized to accept an edge of a substrate. An outer portion of the top surface of the inner silicon ring is configured to contact in the overlap region and underlying an inner portion of the bottom surface of the outer ceramic ring such that the overlap is disposed over the cathode electrode.

In yet another embodiment, a method for tuning an etch rate with a ring assembly is provided. The method includes etching a first substrate circumscribed by the ring assembly, the ring assembly having a ceramic outer ring and a silicon inner ring mating to define an overlap region; replacing at least one of the ceramic outer ring and the silicon inner ring to change the overlap region; and etching a second substrate in the presence of the ring assembly having the changed overlap region.

### BRIEF DESCRIPTION OF THE DRAWINGS

So that the manner in which the above recited features of the embodiments herein are attained and can be understood in detail, a more particular description of the invention, briefly summarized above, may be had by reference to the embodiments thereof which are illustrated in the appended drawings.

FIG. 1 depicts a plasma processing chamber having a tunable ring assembly, according to an embodiment.

FIG. 2 depicts a partial sectional view of the tunable ring assembly depicted in FIG. 1, illustrating an inner ring and an outer ring.

FIG. 3 illustrates overlapping portions of inner and outer rings.

FIG. 4 illustrates a graph depicting etch rates for various configurations of the ring assembly.

To facilitate understanding of the embodiments, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention provide a tunable ring assembly that allows the lateral uniformity of plasma ions to be controlled across a surface of a substrate undergoing plasma processing. The tunable ring assembly enables the control of the critical dimensions along the edge of a substrate by modifying the mixture and concentration of ions along the edge of the substrate. Beneficially, the tunable ring assembly enables etching of high aspect ratio (HAR) features in stacked circuits or three dimensional integrated circuits (3D IC) while maintaining control over the feature's CD.

The novel tunable ring assembly provides an exposed top quartz surface at an outside edge and an exposed top surface at an inside edge. The silicon surface at the inside edge is configured to extend partially below a substrate in a plasma processing chamber during an etch process. The quartz surface partially overlies the silicon surface. The amount of overlap may be adjusted, or tuned, to control the etching along the edge of the substrate adjacent to the silicon surface. The percent that the quartz surface of the ring assembly may overlap the silicon surface ranges from about 0% to about 100% so as to substantially control the flow of plasma ions in and around the edge of the substrate.

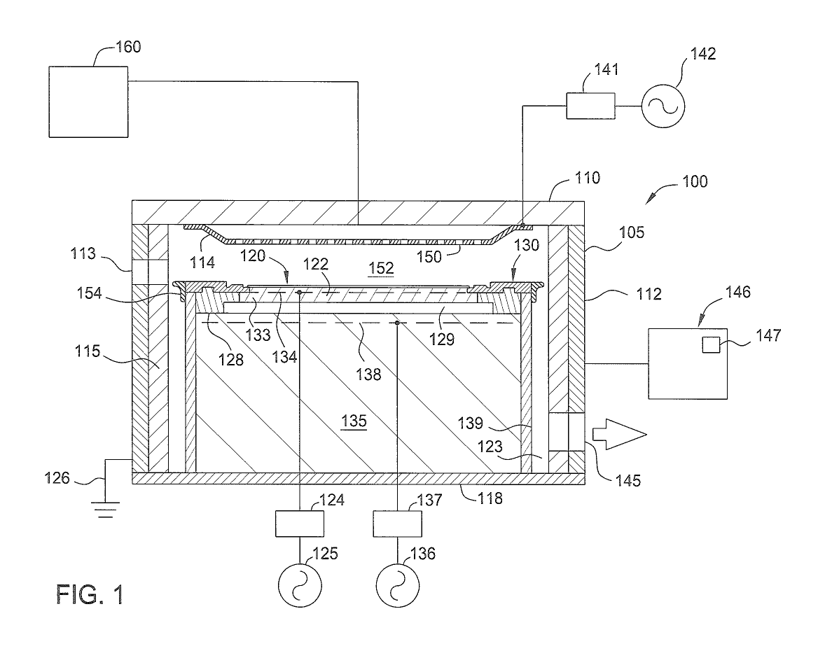

FIG. 1 illustrates an exemplary processing chamber 100 having a tunable ring assembly 130. The exemplary processing chamber 100 is configured as an etch processing chamber and is suitable for removing one or more material layers from a substrate. One example of the process chamber that may be adapted to benefit from the invention is an Applied CENTURA® Avatar™ Etch processing chamber, available from Applied Materials, Inc., located in Santa Clara, Calif. It is contemplated that other process chambers, including those from other manufactures, may be adapted to practice embodiments of the invention.

The processing chamber 100 includes a chamber body 105 enclosed by a chamber lid assembly 110 and defining a processing chamber volume 152 therein. The chamber body 105 has sidewalls 112 and a bottom 118 and a ground shield assembly 126 coupled thereto. The sidewalls 112 have a liner 115 to protect the sidewalls 112 and extend the time between maintenance cycles of the processing chamber 100. The dimensions of the chamber body 105 and related components of the processing chamber 100 are not limited and generally are proportionally larger than the size of a substrate 120 to be processed. Examples of substrate sizes include, among others, substrates 120 with a 150 mm diameter, 200 mm diameter, a 300 mm diameter and 450 mm diameters, among others.

The chamber body 105 may be fabricated from aluminum or other suitable materials. A substrate access port 113 is formed through the sidewall 112 of the chamber body 105, facilitating the transfer of the substrate 120 into and out of the processing chamber 100. The access port 113 may be coupled to a transfer chamber and/or other chambers of a substrate processing system (both not shown).

A pumping port 145 is formed through the sidewall 112 of the chamber body 105 and connected to the chamber volume through the exhaust manifold 123. A pumping device (not shown) is coupled to the processing chamber volume 152 to evacuate and control the pressure therein. The exhaust manifold 123 has a baffle plate 154 to control the uniformity of the plasma gas drawn into the exhaust manifold 123 from the pumping device. The pumping device may include one or more pumps and throttle valves. The pumping device and chamber cooling design enables high base vacuum (about 1×E⁸ Torr or less) and low rate-of-rise (about 1,000 mTorr/min) at temperatures suited to thermal budget needs, e.g., about −25 degrees Celsius to about +500 degrees Celsius. In one embodiment, the pumping device enables a vacuum pressure between 10 and 30 mT.

A gas source 160 is coupled to the chamber body 105 to supply process gases into the processing chamber volume 152. In one or more embodiments, process gases may include inert gases, non-reactive gases, and reactive gases if necessary. The process gases that may be provided by the gas source 160 includes, but are not limited to, a carbon containing gas optionally accompanying by an oxygen containing gas and/or an inert gas. Examples of the carbon containing gas include CO₂, CO, CH₄, C₂H₄, C₂H₆, CH₂F₂, CₓF_{y}H_{z}, COS and the like. Examples of the oxygen containing gas include O₂, NO, N₂O, CO₂, CO, COS, and the like. Alternatively, a carrier gas, such as N₂. Ar or He, may also be incorporated with the hydro-fluorocarbon gas into the processing chamber 100. Additional combinations of gases may be supplied to the chamber body 105 from the gas source 160. For instance, a mixture of HBr and O₂ may be supplied into the processing volume to etch a silicon (Si) substrate. In one embodiment, the process gas supplied in the etching gas mixture is COS/O₂/N₂/CH₄.

The lid assembly 110 generally includes a shower head 114. The shower head 114 has a plurality of gas delivery holes 150 for introducing process gas from the gas source 160 into the processing chamber volume 152. The shower head 114 is connected to an RF power supply 142 through a match circuit 141. The RF power provided to the shower head 114 energizes the process gases exiting the shower head 114 to form plasma within the processing chamber volume 152.

A substrate support pedestal 135 is disposed below the shower head 114 in the processing chamber volume 152. The substrate support pedestal 135 may include an electro-static chuck (ESC) 122 for holding the substrate 120 during processing. The tunable ring assembly 130 is disposed on the ESC 122 and along the periphery of the substrate support pedestal 135. The tunable ring assembly 130 is configured to control the distribution of etching gas radicals at the edge of the substrate 120, while shielding the top surface of the substrate support pedestal 135 from the plasma environment inside the processing chamber 100.

The ESC 122 is powered by an RF power supply 125 integrated with a match circuit 124. The ESC 122 comprises an electrode 134 embedded within a dielectric body 133. The RF power supply 125 may provide a RF chucking voltage of about 200 volts to about 2000 volts to the electrode 134. The RF power supply 125 may also be coupled to a system controller for controlling the operation of the electrode 134 by directing a DC current to the electrode for chucking and de-chucking the substrate 120. An isolator 128 circumscribes the ESC 122 for the purpose of making the sidewall of the ESC 122 less attractive to the plasma ions. Additionally, the substrate support pedestal 135 has a cathode liner 139 to protect the sidewalls of the substrate support pedestal 135 from the plasma gasses and to extend the time between maintenance of the plasma processing chamber 100. The cathode liner 139 and the liner 115 may be formed from a ceramic material. For example, both the cathode liner 139 and liner 115 may be formed from Yttria.

A cooling base 129 is provided to protect the substrate support pedestal 135 and assists in controlling the temperature of the substrate 120. The cooling base 129 and ESC 122 work together to maintain the substrate temperature within the temperature range required by the thermal budget of the device being fabricated on the substrate 120. The ESC 122 may include heaters for heating the substrate, while the cooling base 129 may include conduits for circulating a heat transfer fluid to sinking heat from the ESC 122 and substrate disposed thereon. For example, the ESC 122 and cooling base 129 may be configured to maintain the substrate 120 at a temperature of about minus 25 degrees Celsius to about 100 degrees Celsius for certain embodiments, at a temperature of about 100 degrees Celsius to about 200 degrees Celsius temperature range for other embodiments, and at about 200 degrees Celsius to about 500 degrees Celsius for yet still other embodiments. In one embodiment, the ESC 122 and cooling base 129 maintain the substrate 120 temperature at about 15 degrees Celsius to about 40 degrees Celsius.

Lift pins (not shown) are selectively moved through the substrate support pedestal 135 to lift the substrate 120 above the substrate support pedestal 135 to facilitate access to the substrate 120 by a transfer robot or other suitable transfer mechanism.

A cathode electrode 138 is disposed in the substrate support pedestal 135 and connected to an RF power source 136 through an integrated match circuit 137. The cathode electrode 138 capacitively couples power to the plasma from below the substrate 120. In one embodiment, the RF power source 136 provides the cathode electrode 138 with between about 200 W to about 1000 W of RF power.

A controller 146 may be coupled to the processing chamber 100. The controller may include a central processing unit (CPU) 147, a memory, and support circuits. The controller is utilized to control the process sequence, regulating the gas flows from the gas source 160 into the processing chamber 100, the power to power supplies 136, 142 and other process parameters. The CPU 147 may be of any form of a general purpose computer processor that can be used in an industrial setting. The software routines can be stored in the memory, such as random access memory, read only memory, floppy or hard disk drive, or other form of digital storage. The support circuits are conventionally coupled to the CPU 147 and may comprise cache, clock circuits, input/output subsystems, power supplies, and the like. The software routines, when executed by the CPU 147, transform the CPU 147 into a specific purpose computer (controller) that controls the processing chamber 100 such that the processes are performed in accordance with the present invention. The software routines may also be stored and/or executed by a second controller (not shown) that is located remotely from the processing chamber 100.

During processing, gas is introduced into the processing chamber 100 to form a plasma and etch the surface of the substrate 120. The substrate support pedestal 135 is biased by the power source 136. Power supply 142 energizes the process gas, supplied by the gas source 160, leaving the shower head 114 to form the plasma. Ions from the plasma are attracted to the cathode in the substrate support pedestal 135 and bombard/etch the substrate 120. The tunable ring assembly 130 further controls the distribution of etchants at the edge of the substrate, so that the edge to center etch uniformity may be controlled to obtain desired etching results.

In one embodiment, the substrate 120 is etched with high aspect ratio features. Several process parameters are regulated while the etching mixture is supplied into the processing chamber. The chamber pressure in the presence of the etching gas mixture is regulated between about 10 mTorr to about 30 mTorr. The temperature of the substrate 120 is maintained between about 15 degrees Celsius to about 40 degrees Celsius. A process gas of COS/0₂/N₂/CH₄ may be supplied by the gas source 160 through the shower head 114 into the processing chamber volume 152. The power supply 142 energizes the process gas to form a plasma gas with ions attracted to the substrate 120 by application of about 200 W to about 1000 W of RF bias power applied to the bias power electrode 138.

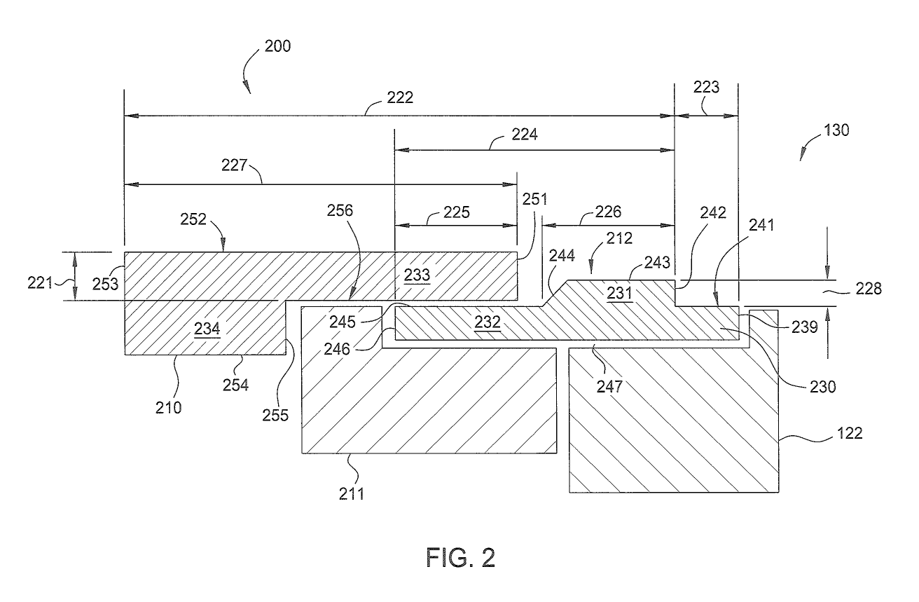

The configuration of the tunable ring assembly 130 in the plasma processing chamber 100 may be selected in response to the processing parameters utilized to etch a particular material disposed on the substrate 120. The configuration of the elements comprising the tunable ring assembly 130 may be selected to control the distribution of the plasma ions across the surface to the substrate 120, and may also be selected to control the amount of oxygen provided at the edge of the substrate which intern assists in polymer control and opening of the apertures of the mask through which the underlying layers disposed on the substrate are etched. To better understand the relationship between the elements of the tunable ring assembly 130 and the distribution of plasma constituents across the surface and along the edge of substrate 120, the tunable ring assembly 130 is described in greater detail with reference to FIG. 2.

FIG. 2 is a partial sectional view of the tunable ring assembly 130 illustrated in FIG. 1. The tunable ring assembly 130 has a ring-shaped multi-component body 200 that includes an inner silicon ring 212 and an outer quartz ring 210. The tunable ring assembly 130 may optionally include a middle quartz ring 211. The middle quartz ring 211 is mounted on the exterior of the substrate support pedestal 135 and acts as an edge protection ring (EPR) to prevent arcing at the ESC 122 by preventing the presence of line of sight passages between the ESC and the plasma environment within the chamber.

The inner silicon ring 212 has a radially inner portion 230, a middle portion 231 and a radially outer portion 232. The inner silicon ring 212 has a bottom surface 247 which defines a common bottom for each of the inner, middle and outer portions 230, 231 232. The inner portion 230 of the inner silicon ring 212 faces a center (e.g., centerline) of the tunable ring assembly 130.

The inner portion 230 has atop surface 241 which is dimensioned to underlie the substrate 120, as shown in FIG. 1. The top surface 241 of the inner portion 230 is bounded between an inner surface 239 and an intermediate face 242. The inner surface 239 defines the innermost diameter of the inner silicon ring 212, and in one embodiment, has a cylindrical form. The top surface 241 extends from the top of the inner surface 239 to the bottom of the intermediate face 242. The intermediate face 242 extends upwards from the top surface 241 to a top surface 243 of the middle portion 231. The top surface 241and intermediate face 242 forms a notch in the inner silicon ring 212 on which a substrate overlays.

The intermediate face 242 has a height 228 which is indicative of the vertical difference between the top surface 243 and the top surface 241. The height 228 may be from about 0 mm to about 5 mm such as between about 1 mm and about 1.5 mm. In one embodiment, the intermediate face 242 of the tunable ring assembly 130 has a height 228 of about 1.1 mm.

The top surface 241 of the inner portion 230 has a dimension 223 measured along a radii of the tunable ring assembly 130 from the inner surface 239 to the intermediate face 242. The top surface 241 dimension 223 may range in the from about 2 mm to about 15 mm depending on process requirements, such as between about 4 mm and about 10 mm. In one embodiment, top surface 241 of the tunable ring assembly 130 has a dimension 223 of about 6 mm.

The middle portion 231 of the inner silicon ring 212 is disposed immediately adjacent and radially outward of the inner portion 230. The middle portion 231 includes the intermediate face 242 which extends above the top surface 241 of the inner portion 230, the top surface 243, and an inclined surface 244. The inclined surface 244 connects the top surface 243 and the outer portion 232. The inclined surface 244 may be oriented at an angle of about 45 degree to minimize erosion of the ring assembly 130 due to sputtering.

The top surface 243 of the middle portion 231 is substantially horizontal and located between the intermediate face 242 and the inclined surface 244. The top surface 243 may be parallel to the top surface 241. The top surface 243 is dimensioned to be immediately outward of the edge of the substrate 120 to provide a silicon surface that functions as a continuation of the surface of the substrate 120 to promote more uniform plasma conditions between the edge and center of the substrate 120 during processing.

The middle portion 231 has a horizontal length which extends beyond the top surface 243 and includes a projection of the inclined surface 244. The horizontal projection for the middle portion 231 has a dimension 226 which may be less than about 30 mm, such as between about 10 mm and about 20 mm. In one embodiment, the horizontal dimension 226 of the middle portion 231 is about 20 mm.

The outer portion 232 of the inner silicon ring 212 is immediately adjacent to and radially outward of the middle portion 231 of the inner silicon ring 212 and opposite the inner portion 230. The outer portion 232 includes a top surface 245 and a far surface 246. The top surface 245 may be parallel with the top surface 243, and in one embodiment, is coplanar with the top surface 241. The far surface 246 may have a cylindrical orientation and defines the outside diameter of the inner silicon ring 212.

The middle portion 231 and the outer portion 232 of the inner silicon ring 212 combine to form a region of the inner silicon ring 212 which is not covered by the substrate 120 during processing. This uncovered region determines the silicon mass affecting the etch rate. A silicon mass which is too large scavenges the etchant and the etch rate at the edge of the substrate could drop, leading to poor center to edge etch rate uniformity. Conversely, reducing the silicon mass may increase the etch rate. The uncovered silicon region has a dimension 224. The dimension 224 of the uncovered region may range from about 20 mm to about 40 mm, such as between about 25 mm to about 35 mm. In one embodiment, the dimension 224 is about 33 mm.

The outer quartz ring 210 extends partially over the outer potion 232. The amount that the outer quartz ring 210 extends over the outer potion 232 may be selected to control the amount of exposed silicon in the uncovered region defined by dimension 224. Thus, inside diameter of the outer quartz ring 210 may be selected to control the center to edge etch rate uniformity without having to alter the configured of the inner silicon ring 232. For example, when needed, one outer quartz ring 210 may be replaced with another outer quartz ring 210 having a different inside diameter to change amount of exposed silicon of the inner silicon ring 232 so as to control the center to edge etch rate uniformity.

Additionally, the quartz material comprising the outer quartz ring 210 provides an oxygen source at the edge of the substrate during processing. The oxygen provided by the outer quartz ring 210 can be used to control etch parameters such as polymer deposition while etching and the size of apertures formed through the etch mask (such as a photoresist or carbon-based hardmask). For example, having more oxygen available near the edge of the substrate will increase the size (or reduce the closure rate) of apertures formed through etch mask preferentially relative to that proximate the center of the substrate. Thus, the inside diameter of the outer quartz ring 210 may be utilized to tune the edge to center etch results of the etch process.

Continuing to refer to FIG. 2, the outer quartz ring 210 has an overlap portion 233 and an outer portion 234. Atop surface 252 of the outer quartz ring 210 defines an upper surface and the overlap and outer portions 233, 234. The top surface 252 of the outer quartz ring 210 has a dimension 227 which may range between about 30 mm and about 50 mm, for example, about 40 mm.

The overlap portion 233 defines the inner portion of the outer quartz ring 210, which is radially inward of the outer portion 234. The overlap portion 233 has a bottom surface 256 and an inner surface 251. The bottom surface 256 of the overlap portion 233 of the outer quartz ring 210 is configured to mate and contact with the top surface 245 of the inner silicon ring 212 such that the outer quartz ring 210 overlaps and covers a portion of the top surface 245 of the inner silicon ring 212. A dimension 225 of the overlap between the inner silicon ring 212 and the outer quartz ring 210 is measured along a radius of the tunable ring assembly 130, and extends from the inner surface 251 of the outer quartz ring 210 to the far surface 246 of the inner silicon ring 212. The overlap dimension 225 may be less than about 30 mm, such as between about 10 mm and about 20 mm. In one embodiment, the overlap dimension 225 is about 20 mm. In one embodiment the overlap region dimension 225 extends along the inner silicon ring to about 30 mm from the notch at intermediate face 242.

Selection of the dimension 225 of the overlap may change a dimension 227 for the top surface 252 of the outer quartz ring 210. As the dimension 226 of the middle portion 231 for the inner silicon ring 212 is minimized and approaches 0 mm, the portion of the tunable ring assembly 130 exposed to the plasma, predominantly defined by dimension 227, becomes essentially overlapped by the quartz. In this manner the proximity of the outer quartz ring 210 is tunable relative to the position of the substrate, thus bringing more oxygen generating material closer to the edge of the substrate 120 while encourages an increase in the etch rate at the edge of the substrate 120 by minimizing the amount of silicon material exposed by the inner silicon ring 212. An overall length dimension 222 reflects portion of the tunable ring assembly 130 exposed outward of the substrate, in other words, the entire sectional width of the assembly 130 minus the width of the top surface 241. Although the overall length dimension 222 may range between about 40 mm and about 60 mm, the length dimension is not limited to this range. In one embodiment, the overall length dimension 222 is about 60 mm.

The overlap portion 233 has a height equivalent to the length of the inner surface 251, which is generally greater than the length of the intermediate face 242. The height of the overlap portion 233 is generally selected to allow sufficient service life of the outer quartz ring 210 which is consumed during processing.

The portion of the top surface 252 defined over the overlap portion 233 of the outer quartz ring 210 is vertically above the top surface 245 of the inner silicon ring 212, the overlapping portion of the top surface 252 defined by length dimension 253 of the inner surface 251. The length dimension 253 of the inner surface 251 may range between about 1 mm and about 5 mm, such as between about 2 mm and about 3.5 mm. In one embodiment, the inner surface 251 has a length dimension 253 of about 2.5 mm.

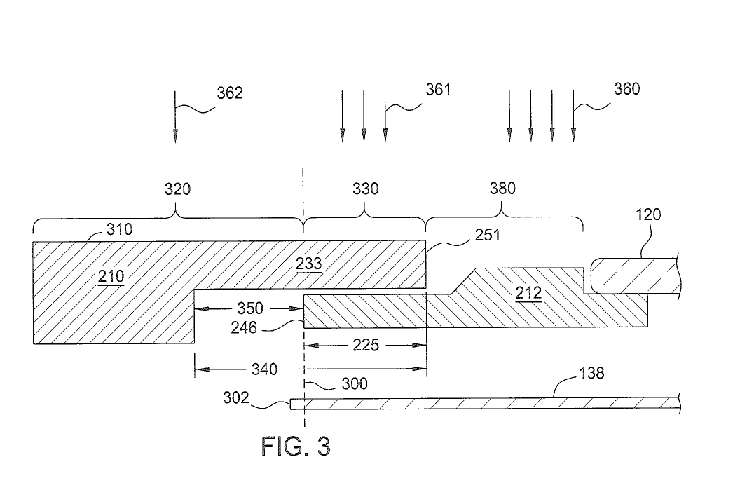

The outer portion 234 of the outer quartz ring 210 has a far side 253, bottom 254 and near side 255. The far side 253 defines the most outer diameter of the tunable ring assembly 130. The near side 255 abuts the middle quartz ring 211. The bottom 254 is parallel to and extends below the bottom surface 256 of the overlapped portion 233, thereby allowing the outer quartz ring 210 to be positionally located on the substrate support pedestal 135. The relationship between the outer quartz ring 210 and the inner silicon ring 212 as well as the affect on etching caused by this relationship is discussed relative to FIG. 3.

FIG. 3 illustrates the overlap between the outer quartz ring 210 and inner silicon ring 212 of the tunable ring assembly 130 above the cathode electrode 138. The relative positions of the outer quartz ring 210 and inner silicon ring 212 of the tunable ring assembly 130 defines an overlap portion 330 and a non-overlap portion 320 of the outer quartz ring 210 which are exposed to the plasma within the processing chamber 100, and an exposed portion 380 of inner silicon ring 212 which is also exposed to the plasma within the processing chamber 100. The other portions of the inner silicon ring 212 are either covered (i.e., shielded from the plasma) by the overlap portion 330 of the outer quartz ring 210 or the substrate 120. The overlap portion 233 of outer quartz ring 210 has a length 340 measured along a radius of the tunable ring assembly 130. A gap 350 is shown between outer quartz ring 210 and inner silicon ring 212. The gap 350 allows for the middle quartz ring 211 to interfit with the rings 210, 212, as shown in FIG. 2.

As shown in FIG. 3, the cathode electrode 138 extends below the inner silicon ring 212 to an outer diameter edge 302 which is radially outward of the far surface 246 of the inner silicon ring 212 and inner surface 251 of the outer quartz ring 210, as illustrated by imaginary line 300. The extension of the cathode electrode 138 below the inner silicon ring 212 improves plasma uniformity at the edge of the substrate 120. The inner silicon ring 212 may provide a silicon surface that makes the edge of the substrate appear (to the plasma) outward of it's actually position.

The extension of the cathode electrode 138 below the outer quartz ring 210 preferentially etches the overlap portion 330 of the outer quartz ring 210 relative to the non-overlapped portion 320, thereby releasing oxygen from the quartz material comprising the outer quartz ring 210 proximate the edge of the substrate 120. The released oxygen allows the amount of polymer passivation and size of the opening of the apertures of the mask through which the underlying layers disposed on the substrate are etched to be controlled. For example, having a larger overlap portion 330 will increase the amount of oxygen being released, and thus enlarge or keep clear the opening of the apertures of the mask through which the underlying layers disposed on the substrate are etched. Conversely, having a smaller overlap portion 330 will decrease the amount of oxygen being released, and thus allow the opening of the apertures of the mask to be narrowed while etching. Thus, by controlling the size (i.e., length dimension 225 shown in FIG. 2) of the overlap portion 330, the etch process may be tuned.

Illustrated in FIG. 3 are plasma ions 360 over the inner silicon ring 212, plasma ions 361 near an overlap portion 330 of outer quartz ring 210 and plasma ions 361 non-overlap portion 320 of outer quartz ring 210. The reaction rate for the plasma ions 360 may be adjusted by changing the size of overlap portion 330 of outer quartz ring 210. The reaction rate increases as the number of plasma ions increase. As shown, the reaction rate nearest to the substrate, shown by the number of arrows depicting plasma ions 360, is higher than the reaction rate further from the substrate. An increase in plasma ions 360 corresponds to an increase in the reaction rate near the edge of the substrate. In the example shown, plasma ions 360 bombard the exposed portion 380 of the inner silicon ring 212, plasma ions 361 bombard the overlap portion 330, while plasma ions 362 bombard the non-overlap portion 320. Therefore the amount of plasma ions 360, 361, 362 are non-uniform across the tunable ring assembly 130, with the concentration of the ions decreasing as the distance from the center of the ring assembly increases.

In one embodiment, the plasma reacting rate at the substrate edge may be tuned by reducing the size of the overlap portion 330 for the outer quartz ring 210 over the inner silicon ring 212. This has the effect of decreasing the number of plasma ions 360.

In another embodiment, the plasma reaction rate over a substrate is non-uniform. The number of plasma ions reacting at the edge of the substrate is not sufficient to etch the substrate at the same rate as the middle of the substrate. The overlap portion 330 of outer quartz ring 210 may be increased to cover more inner silicon ring 212. The length 340 is increased to correspondingly increase the overlap dimension 225, and the number of plasma ions 360 is thus increased as well. Alternatively, the etch rate may be tuned to be non-uniform in a particular manner such that a substrate with high aspect ratio features in one area may be etched more rapidly. One such example is steps which may be found in 3D packaging.

As can be seen, the reaction rate at a substrate edge can be tuned by adjusting the dimension 225 of overlap portion 330 of the outer quartz ring 210. In one embodiment, where the reaction rate along a substrate edge is too low, the overlap portion 330 may be increased by changing one of the rings 210, 212.

Since the exposure of chamber components to plasma ions greatly affects the service life and maintenance interviews, the ability to control the amount of ions impacting the ring assembly 130 advantageously extends the service life. The ring assembly 120 not only protects the ESC, but also enhances the plasma process by assisting with controlling uniformity of the plasma ions across the surface of the substrate.

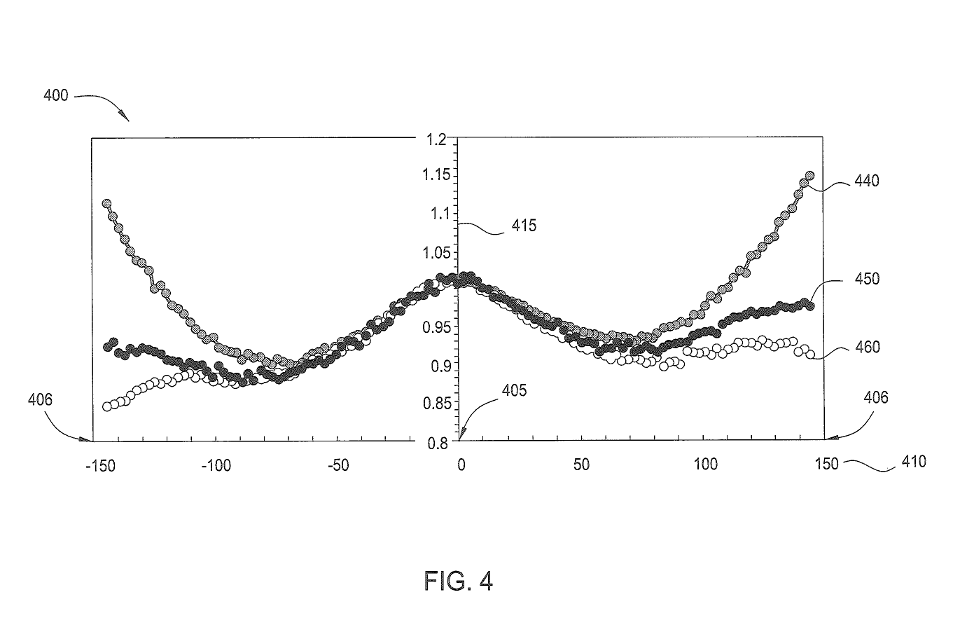

To better illustrate the differences between various embodiments. FIG. 4 provides a graph 400 depicting the etch rate for the various assembly ring configurations. The graph 400 depicts three embodiments. In a first embodiment, a ring assembly 120 having no overlapping portions (i.e., length 255 is approximately zero) is shown by trace 460. In a second embodiment, a ring assembly 120 having about 50 percent of the outer portion 232 overlapped with the outer quartz ring 210 is shown by trace 450. In a third embodiment, a ring assembly 120 having about 100 percent of the outer portion 232 overlapped with the outer quartz ring 210 is shown by trace 440. The traces 440, 450, 460 are graphed with an axis 415 depicting the etch rate in Angstroms/minute and axis 410 illustrating the radial position on the substrate 120, with reference numeral 405 indicating the center of the substrate 120 and reference numeral 406 indicating the edge.

In a first embodiment illustrate by trace 460, the exposed portion of the ring assembly is mostly comprised of silicon near the substrate edge and the etch rate at the substrate edge is most influenced by the silicon. As seen at the outer radius 410 trace 460, the etch rate drops off at the proximate the edge 406.

In a second embodiment illustrated by trace 450, the ring assembly is comprised of quartz and silicon with the silicon portion nearest to the substrate edge. The etch rate is now partially influenced by the amount of quartz exposed to the plasma proximate the edge of the substrate. As seen at the outer radius 410 for the trace 450, the etch rate at the edge 406 is nearly the same as that in the center 405 of the substrate 120.

In a third embodiment illustrated by trace 450, the ring assembly is comprised of quartz right to the substrate edge. The etch rate is significantly influenced by the amount of quartz exposed to the plasma proximate the edge of the substrate. As seen at the outer radius 410 for the trace 440, the etch rate at the edge 406 increases substantially relative to the etch rate for the center 405 of the substrate 120.

While the foregoing is directed to embodiments of the present invention, other and further embodiments of the invention may be devised without departing from the basic scope thereof, and the scope thereof is determined by the claims that follow:

What is claimed is:

1. A ring assembly comprising:
an outer ceramic ring having an exposed top surface and a bottom surface; and
an inner silicon ring configured to mate with the outer ceramic ring to define an overlap region, the inner silicon ring having an inner surface, a top surface and a notch formed between the inner surface and the top surface, the inner surface defining an inner diameter of the ring assembly, the notch is sized to accept an edge of a substrate, an outer portion of the top surface of the inner silicon ring configured to contact in the overlap region and underlying an inner portion of the bottom surface of the outer ceramic ring.

2. The ring assembly of claim 1 further comprises a middle ceramic ring underlying the overlap region of the inner silicon ring underlying the inner portion of the bottom surface of the outer ceramic ring.

3. The ring assembly of claim 1 wherein the overlap region extends to the notch.

4. The ring assembly of claim 1 wherein the overlap region has a radial dimension between about zero and about 30 mm.

5. The ring assembly of claim 1 wherein the outer ceramic ring extends along the inner silicon ring to about 30 mm from the notch.

6. The ring assembly of claim 1 wherein the top surface of the inner silicon ring includes an angled surface facing radially outward and upward from the notch.

7. The ring assembly of claim 6 wherein the angled surface is oriented at about 45 degrees relative to the top surface of the inner silicon ring.

8. A plasma processing chamber comprising:
a chamber body;
a substrate support pedestal disposed in the chamber body and having a cathode electrode disposed therein;
a ring assembly disposed on the substrate support pedestal, the ring assembly comprising:
an outer ceramic ring having an exposed top surface and a bottom surface; and
an inner silicon ring configured to mate with the outer ceramic ring to define an overlap region, the inner silicon ring having an inner surface, a top surface and a notch formed between the inner surface and the top surface, the inner surface defining an inner diameter of the ring assembly, the notch is sized to accept an edge of a substrate, an outer portion of the top surface of the inner silicon ring configured to contact in the overlap region and underlying an inner portion of the bottom surface of the outer ceramic ring and wherein the overlap is disposed over the cathode electrode.

9. The plasma processing chamber of claim 8, wherein the cathode electrode extends beyond the inner silicon ring.

10. The plasma processing chamber of claim 8, further comprises a middle ceramic ring underlying the overlap region of the inner silicon ring underlying the inner portion of the bottom surface of the outer ceramic ring.

11. The plasma processing chamber of claim 8, wherein the overlap region extends to the notch.

12. The plasma processing chamber of claim 8, wherein the overlap region has a radial dimension between about zero and about 30 mm.

13. The plasma processing chamber of claim 8, wherein the outer ceramic ring extends along the inner silicon ring to about 30 mm from the notch.

14. The plasma processing chamber of claim 8, wherein the top surface of the inner silicon ring includes an angled surface facing radially outward and upward from the notch.

15. The plasma processing chamber of claim 14, wherein the angled surface is oriented at about 45 degrees relative to the top surface of the inner silicon ring.

16. A method for tuning an etch rate with a ring assembly, the method comprising:
etching a first substrate circumscribed by the ring assembly, the ring assembly having a ceramic outer ring and a silicon inner ring mating to define an overlap region;
replacing at least one of the ceramic outer ring and the silicon inner ring to change the overlap region; and
etching a second substrate in the presence of the ring assembly having the changed overlap region.

17. The method of claim 16 wherein replacing comprises:
increasing a dimension of the overlap region.

18. The method of claim 16 wherein replacing comprises:
decreasing a dimension of the overlap region.

19. The method of claim 16 wherein etching the first substrate comprises:
energizing a cathode electrode to drive oxygen from the ceramic outer ring.
